(19) United States
(12) Patent Application Publication
(10) Pub. No.: US 2025/0214818 A1
(43) Pub. Date: Jul. 3, 2025

(54) SYSTEM FOR TRANSPORTING ARTICLES

(71) Applicant: SEMES CO., LTD., Chungcheongnam-do (KR)

(72) Inventors: Seung Keun JUN, Gyeonggi-do (KR); Eun Sang YOON, Gyeonggi-do (KR); Min Beom KIM, Seoul (KR)

(21) Appl. No.: 19/003,940

(22) Filed: Dec. 27, 2024

(30) Foreign Application Priority Data
Dec. 29, 2023 (KR) 10-2023-0197024

(51) Int. Cl. B66F 9/07

(52) U.S. Cl. CPC B66F 9/07

(57) ABSTRACT

Provided is a system for transporting articles that may transport a variety of articles and includes a transport robot implemented in a compact size. The system for transporting articles includes: a rail installed to extend in an up-down direction; a lifting device configured to ascend and descend along the rail; a carriage device installed on the lifting device and configured to mount a first type article or a second type article having different heights; and a control device controlling at least one of the lifting device and the carriage device, wherein the carriage device includes: a base, a support portion installed on the base and moving in the up-down direction with respect to the base, and a gripper installed on a lower portion of the support portion to move along with the movement of the support portion and configured to grip a first top flange of the first type article and a second top flange of the second type article, and the control device differently adjusts a distance between the support portion and the base depending on whether the gripper grips the first type article or the second type article.

### CROSS-REFERENCE TO RELATED APPLICATION

This application claims priority from Korean Patent Application No. 10-2023-0197024 filed on Dec. 29, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a system for transporting articles.

### 2. Description of the Related Art

Within a semiconductor factory, articles are moved by an automatic transport system. The automatic transport system includes, for example, overhead hoist transport (OHT) and overhead shuttle (OHS).

Meanwhile, a tower lifter is used to move transport articles between floors. The tower lifter may be required to transport a variety of articles (e.g., a wafer storage container and a reticle storage container), and may vary in size and gripping method depending on the type of article.

### SUMMARY

Aspects of the present disclosure provide a system for transporting articles that may transport various types of articles and include a transport robot implemented in a compact size.

Aspects of the present disclosure are not limited to the aspects mentioned above, and other aspects not mentioned will be clearly understood by those skilled in the art from the following description.

According to an aspect of the present disclosure, there is provided a system for transporting articles including: a rail installed to extend in an up-down direction; a lifting device configured to ascend and descend along the rail; a carriage device installed on the lifting device and configured to mount a first type article or a second type article having different heights; and a control device controlling at least one of the lifting device and the carriage device, wherein the carriage device includes: a base, a support portion installed on the base and moving in the up-down direction with respect to the base, and a gripper installed on a lower portion of the support portion to move along with the movement of the support portion and configured to grip a first top flange of the first type article and a second top flange of the second type article, and the control device differently adjusts a distance between the support portion and the base depending on whether the gripper grips the first type article or the second type article.

According to another aspect of the present disclosure, there is provided a system for transporting articles, the system comprising: a rail installed to extend in an up-down direction; a lifting device configured to ascend and descend along the rail; a robot installed on the lifting device; and a control device controlling at least one of the lifting device and the robot, wherein the robot includes a first carriage device and a second carriage device disposed in the up-down direction, the first carriage device performs a turn motion by a first driver connected to the lifting device, the first carriage device includes: a base, a support portion installed on the base, a second driver installed on the base and moving the support portion in the up-down direction, a third driver installed on the base and moving the support portion and the second driver in a forward and backward direction, and a gripper installed on a lower portion of the support portion and moving along with the movement of the support portion, the gripper is configured to grip a first top flange of a first type article and a second top flange of a second type article, the support portion is configured to support a first bottom surface of a third type article, the control device maintains: a first distance between a bottom surface of the first type article and the base within a first safety distance while the gripper grips the first type article, and a second distance between a bottom surface of the second type article and the base within the first safety distance while the gripper grips the second type article, and the first distance and the second distance are the same as each other.

According to still another aspect of the present disclosure, there is provided a system for transporting articles, the system comprising: a first rail installed to extend in an up-down direction; a lifting device configured to ascend and descend along the first rail; a second rail disposed on a first side of the first rail and installed in a horizontal direction; a third rail disposed on a second side of the first rail and installed in the horizontal direction; a carriage device installed on the lifting device and configured to mount a first type article and a second type article having different heights; and a control device controlling at least one of the lifting device and the carriage device, wherein the carriage device includes: a base, a support portion installed on the base and moving in the up-down direction with respect to the base, and a gripper installed on a lower portion of the support portion and moving along with the movement of the support portion, the gripper is configured to grip a first top flange of the first type article and a second top flange of the second type article, the support portion is configured to support a bottom surface of a third type article, the carriage device: moves along the first rail and transports the first type article to the second rail, and moves along the first rail and transports the second type article to the third rail, the control device maintains: a first distance between a bottom surface of the first type article and the base within a first safety distance while the carriage device transports the first type article, and a second distance between a bottom surface of the second type article and the base within the first safety distance while the carriage device transports the second type article, and the first distance and the second distance are the same as each other.

The details of other exemplary embodiments are included in the detailed description and drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a side view for describing a system for transporting articles according to some exemplary embodiments of the present disclosure;

FIG. 2 is a block diagram for describing the system for transporting articles according to some exemplary embodiments of the present disclosure;

FIG. 3 is a perspective view for describing a robot illustrated in FIG. 1;

FIG. 4 is a side view for describing a first carriage device;

FIG. 5 is a perspective view for describing a second driver of the first carriage device illustrated in FIG. 4;

FIG. 6 is a perspective view for describing a third driver of the first carriage device illustrated in FIG. 4;

FIG. 7 is a perspective view for describing a support portion of the first carriage device illustrated in FIG. 4;

FIG. 8 is a perspective view for describing a gripper of the first carriage device illustrated in FIG. 4;

FIG. 9 is a view for describing a first operation of the system for transporting articles according to some exemplary embodiments of the present disclosure;

FIG. 10 is a view for describing a second operation of the system for transporting articles according to some exemplary embodiments of the present disclosure;

FIG. 11 is an enlarged view of area Q1 of FIG. 9 and area Q2 of FIG. 10;

FIG. 12 is a view for describing a third operation of the system for transporting articles according to some exemplary embodiments of the present disclosure;

FIG. 13 is an enlarged view of area Q3 of FIG. 12; and

FIG. 14 is a conceptual view for describing the system for transporting articles according to some exemplary embodiments of the present disclosure.

### DETAILED DESCRIPTION OF THE EMBODIMENTS

Hereinafter, embodiments of the present disclosure will be described in detail with reference to the accompanying drawings. Advantages and features of the present disclosure, and a method for achieving the advantages and features will become apparent with reference to the exemplary embodiments described below in detail in conjunction with the accompanying drawings. However, the present disclosure is not limited to the exemplary embodiments disclosed below, but may be implemented in a variety of different forms, these exemplary embodiments will be provided only in order to make the present disclosure complete and allow those skilled in the art to completely recognize the scope of the present disclosure, and the present disclosure is only defined by the scope of the claims. The same reference numbers indicate the same components throughout the specification.

Spatially relative terms “below”, “beneath”, “lower”, “above”, “upper”, and the like, may be used to easily describe correlations between one element or components and another element or components as illustrated in the drawings. The spatially relative terms are to be understood as terms including different directions of the elements at the time of use or operation in addition to directions illustrated in the drawings. For example, when an element illustrated in the drawing is turned over, an element described as being ‘below or beneath’ another element may be located ‘above’ another element. Therefore, an exemplary term ‘below’ may include both of directions of below and above. The element may also be oriented in other orientations, and thus spatially relative terms may be interpreted according to the orientation.

Terms “first”, “second” and the like are used to describe various elements, components, and/or sections but these elements, components, and/or sections are not limited by these terms. These terms are used only in order to distinguish one element, component, or section from another element, component or section. Accordingly, a first element, a first component, or a first section mentioned below may also be a second element, a second component, or a second section within the spirit of the present disclosure.

Hereinafter, exemplary embodiments of the present disclosure will be described in detail with reference to the accompanying drawings. In describing the exemplary embodiments of the present disclosure with reference to the accompanying drawings, components that are the same as or correspond to each other will be denoted by the same reference numerals, and an overlapping description thereof will be omitted.

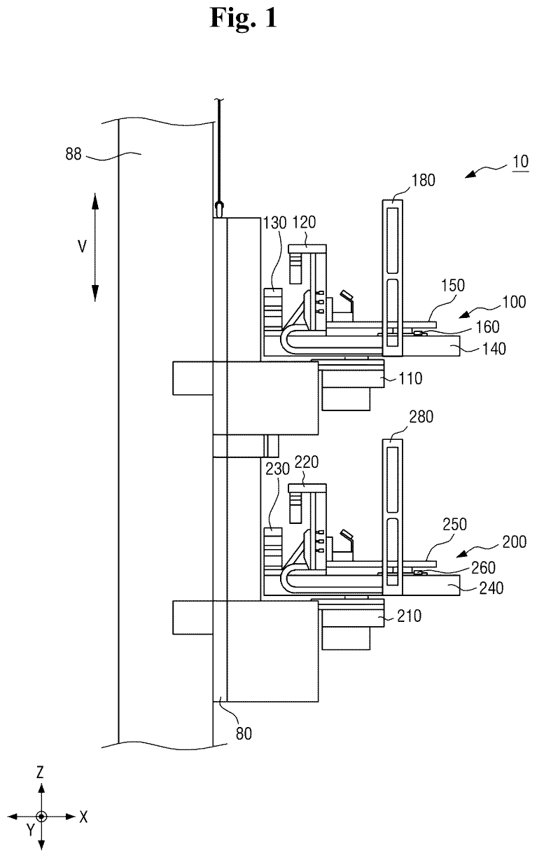

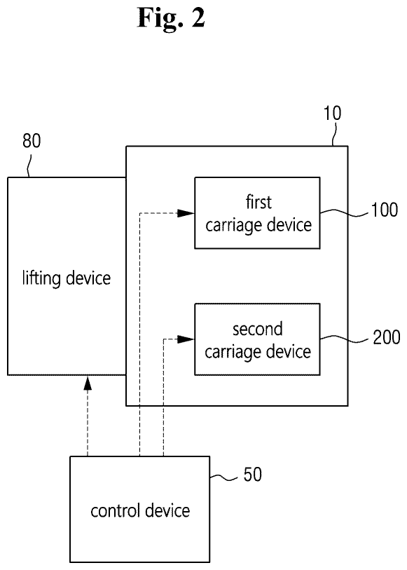

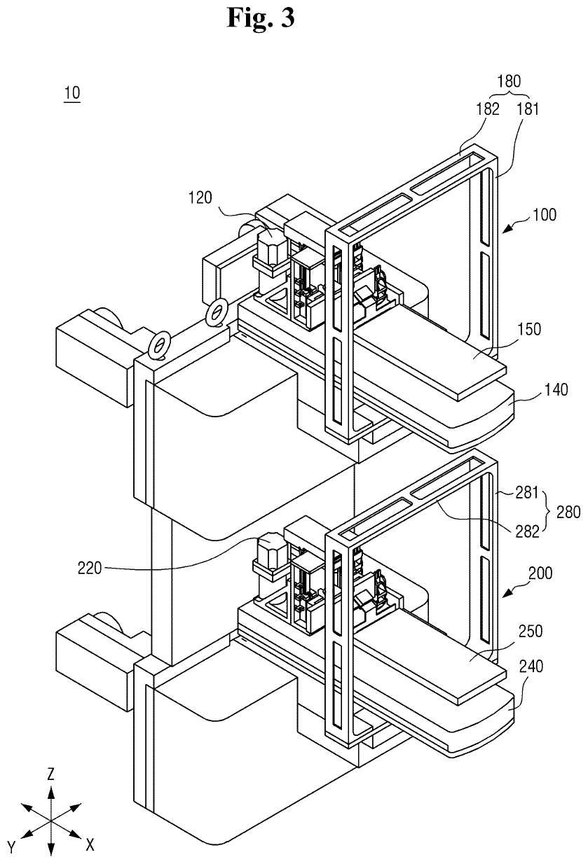

FIG. 1 is a side view for describing a system for transporting articles according to some exemplary embodiments of the present disclosure. FIG. 2 is a block diagram for describing the system for transporting articles according to some exemplary embodiments of the present disclosure. FIG. 3 is a perspective view for describing a robot illustrated in FIG. 1.

Referring to FIGS. 1 to 3, a system for transporting articles (i.e., a tower lifter) includes a lifting device 80, a robot 10, and a control device 50.

The system for transporting articles moves the articles in an up-down direction (or vertical direction) (Z direction) (see drawing symbol V). In this regard, the control device 50 controls an operation of at least one of the lifting device 80 and the robot 10.

A rail 88 is installed along a transport path so as to extend in the up-down direction (Z direction).

The lifting device 80 may be raised and lowered in various ways along the rail 88. For example, various methods, such as a method using a belt wound around a pair of pulleys installed on the upper and lower sides of the rail, a method using a linear motor (LM) guide and block, and a method using magnetic force may be applied to the lifting device 80.

The robot 10 is installed on the lifting device 80, and the robot 10 also moves along with the movement of the lifting device 80. The robot 10 includes a first carriage device 100 and a second carriage device 200 installed in the up-down direction. It is described in FIGS. 1 and 2 that the robot 10 includes two carriage devices 100 and 200, but the robot 10 may also include one carriage device, or may also include three or more carriage devices.

Each of the first carriage device 100 and the second carriage device 200 may perform an in-out operation. That is, each of the first carriage device 100 and the second carriage device 200 may perform a projecting operation and a withdrawing operation. In order to implement such operations, each of the first carriage device 100 and the second carriage device 200 may include a link configuration capable of performing bending and stretching operations, but is not limited thereto. As long as the first carriage device 100 and the second carriage device 200 are configured to be movable or deformable for picking up the article, the first carriage device 100 and the second carriage device 200 may be of any type.

Specifically, the first carriage device 100 includes a first driver 110, a second driver 120, a third driver 130, a base 140, a support portion 150, a gripper 160, a falling prevention portion 180, etc.

The base 140 is connected to the lifting device 80 and performs a turn operation by the first driver 110.

The support portion 150 may be installed on the base 140 and may move along with the movement of the base 140. That is, the support portion 150 may perform the turn operation together with the base 140. In addition, the support portion 150 may be moved in a forward and backward direction (X direction) by the third driver 130. Additionally, the support portion 150 may be moved in the up-down direction (Z direction) with respect to the base 140 by the second driver 120. That is, even if the base 140 is not moved, the support portion 150 may be moved in the up-down direction by the second driver 120.

The gripper 160 may be installed on a lower side of the support portion 150 and may move along with the movement of the support portion 150.

Meanwhile, the gripper 160 may selectively grip a first type article or a second type article. For example, the gripper 160 grips a first top flange of the first type article or grips a second top flange of the second type article.

The first type article and the second type article may be of different types. Accordingly, the shape, size, and height of a container may be different. The first type article and the second type article may be reticle storage containers. For example, the first type article may be a EUV POD and the second type article may be an RSP-150, but is not limited thereto. The EUV POD and RSP-150 have different sizes and heights.

In addition, the support portion 150 may support a third type article that is different from the first type article and the second type article. An upper surface of the support portion 150 may be in contact with a bottom surface of the third type article, thereby supporting the third type article. The third type article may be a wafer storage container, for example, a front opening unified pod (FOUP). A plurality of pins are installed on the upper surface of the support portion 150, so that the plurality of pins may be combined with holes on the bottom surface of the third type article.

Additionally, the support portion 150 may support a fourth type article that is different from the first to third type articles. The fourth type article may be a wafer storage container, for example, a front opening shipping box (FOSB).

The falling prevention portion 180 is installed on the base 140, thereby preventing the first or second type article gripped by the gripper 160 and the third or fourth type article supported by the support portion 150 from falling. The falling prevention portion 180 includes a first member 181 extending in the up-down direction (Z direction) and a second member 182 connected to the first member 181 and crossing the support portion 150 in a Y direction, on both sides of the support portion 150.

The second carriage device 200 may have substantially the same configuration as the first carriage device 100. The second carriage device 200 includes a first driver 210, a second driver 220, a third driver 230, a base 240, a support portion 250, a gripper 260, a falling prevention portion 280, etc.

The base 240 is connected to the lifting device 80 and performs a turn operation by the first driver 210. The support portion 250 may be installed on the base 240 and may move along with the movement of the base 240.

The support portion 250 may be moved in the forward and backward direction (or the X direction) by the third driver 230, and may be moved in the up-down direction (or the Z direction) with respect to the base 240 by the second driver 220.

The gripper 260 may be installed on a lower side of the support portion 250 and may move along with the movement of the support portion 250. The gripper 260 may selectively grip a first type article or a second type article. The support portion 250 may grip a third type article that is different from the first type article and the second type article. Additionally, the support portion 250 may grip a fourth type article that is different from the first to third type articles.

Hereinafter, for convenience of explanation, the structure and operation of the first carriage device 100 will be mainly described, but the same is applied to the structure and operation of the second carriage device 200.

In the system for transporting articles according to some exemplary embodiment of the present disclosure, the control device 50 may differently adjust a distance between the support portion 150 and the base 140 depending on whether the gripper 160 grips the first type article or the second type article.

Specifically, while the gripper 160 is gripping the first type article, a first distance between a bottom surface of the first type article and the base 140 may be maintained within a first safety distance, and while the gripper 160 is gripping the second type article, a second distance between a bottom surface of the second type article and the base 140 may be maintained within the first safety distance. More specifically, the first distance and the second distance may be substantially the same.

When the support portion 150 selectively mounts a third or fourth type article of different heights, the control device 50 may differently adjust a distance between the uppermost surface of the third/fourth type article and the second member 182 depending on whether the support portion 150 supports the third type article or the fourth type article.

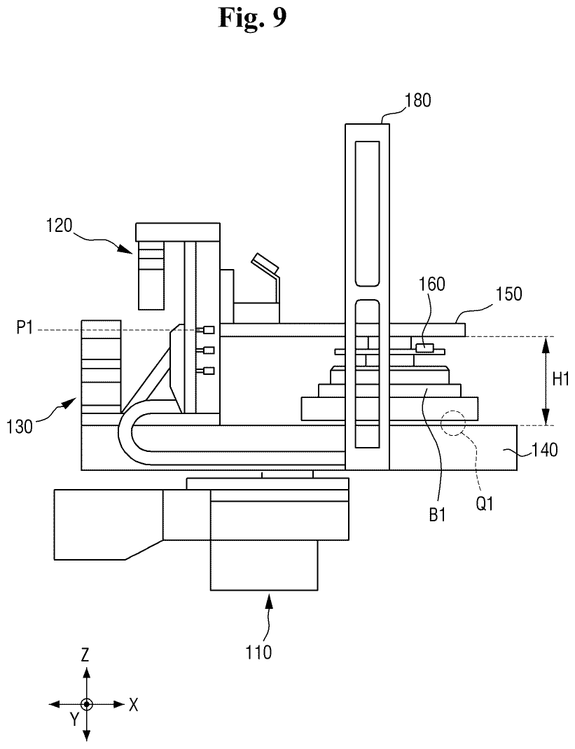

Specifically, while the support portion 150 supports the third type article, a third distance between the uppermost surface of the third type article and the second member 182 is maintained within the second safety distance, and while the support portion 150 supports the fourth type article, a fourth distance between the uppermost surface of the fourth type article and the second member 182 is maintained within the second safety distance. More specifically, the third distance and the fourth distance may be substantially the same. These operations will be described in detail later with reference to FIGS. 9 to 13.

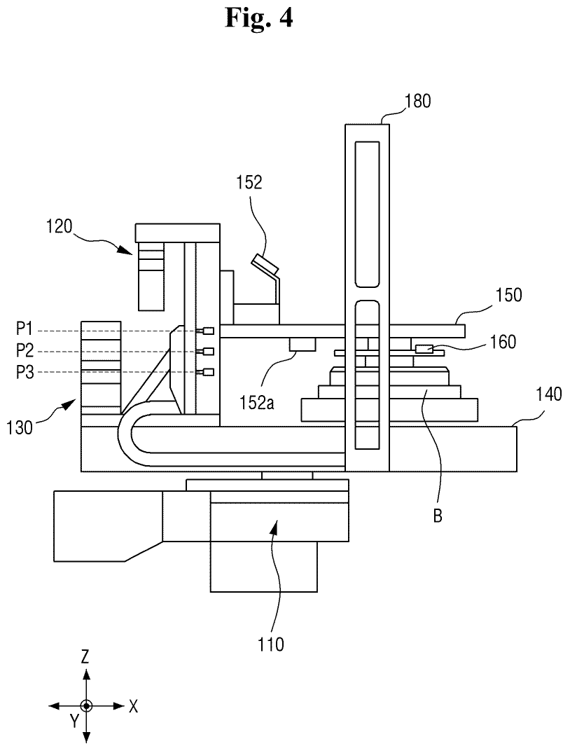

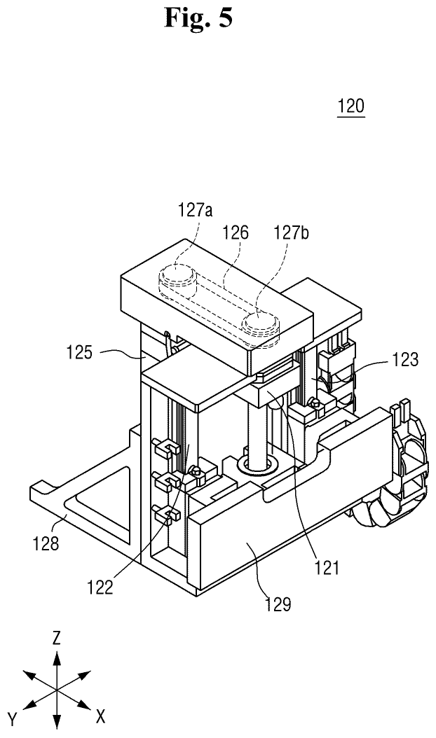

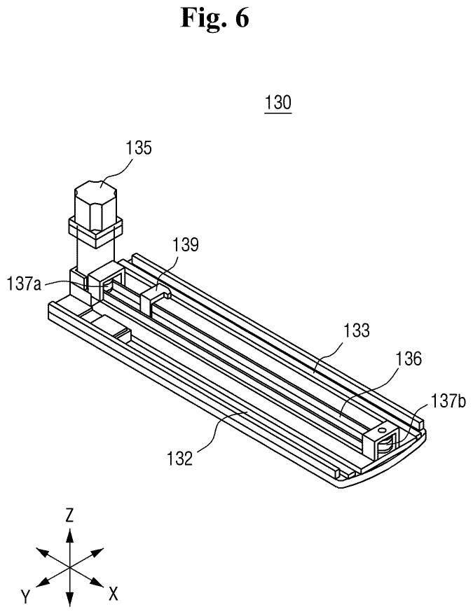

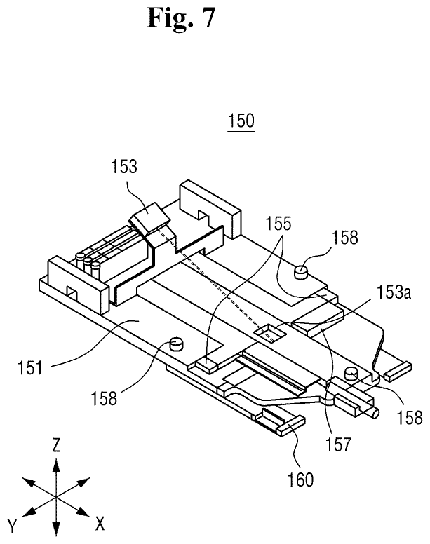

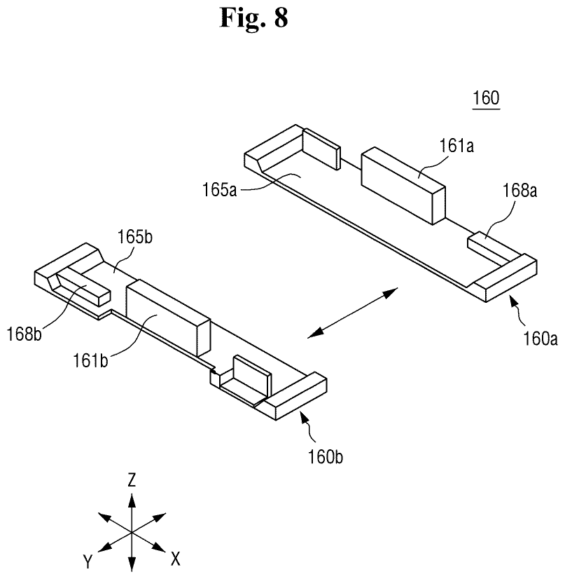

FIG. 4 is a side view for describing a first carriage device. FIG. 5 is a perspective view for describing a second driver of the first carriage device illustrated in FIG. 4. FIG. 6 is a perspective view for describing a third driver of the first carriage device illustrated in FIG. 4. FIG. 7 is a perspective view for describing a support portion of the first carriage device illustrated in FIG. 4. FIG. 8 is a perspective view for describing a gripper of the first carriage device illustrated in FIG. 4.

First, referring to FIGS. 4 and 5, the second driver 120 is installed on the base 140, and the support portion 150 is configured to move in the up-down direction with respect to the base 140. By means of the second driver 120, the support portion 150 and/or the gripper 160 may be moved to a first position P1, a second position P2, and a third position P3 at different heights in the up-down direction.

The second driver 120 includes a ball screw 121, LM guides 122 and 123, a motor 125, a belt 126, pulleys 127a and 127b, a fixed member 129, etc.

The ball screw 121 is installed in a frame 128 so as to extend in the up-down direction (Z direction). The LM guides 122 and 123 are installed on at least one side of the ball screw 121 and parallel to the ball screw 121.

One surface of the fixed member 129 is fixed to the ball screw 121 and/or the LM guides 122 and 123, and the support portion 150 is fixed to the other surface of the fixed member 129.

Members for transmitting a rotational power of the motor 125 to the ball screw 121 may be installed above the ball screw 121. For example, the pulley 127a is connected to the motor 125, the pulley 127b is connected to the ball screw 121, and the two pulleys 127a and 127b are connected to each other by the belt 126. The rotational power of the motor 125 is transmitted to the ball screw 121 through the pulley 127a, the belt 126, and the pulley 127b. By an operation of the ball screw 121, the support portion 150 and/or the gripper 160 may be moved to preset positions P1, P2, and P3.

The first position P1 may be higher than the second position P2, and the second position P2 may be higher than the third position P3. For example, when the gripper 160 intends to grip the first type article, the support portion 150 moves to the first position P1. When the gripper 160 intends to grip the second type article, the support portion 150 moves to the second position P2. When the gripper 160 intends to grip the third type article, the support portion 150 moves to the third position P3.

Referring to FIGS. 4 and 6, the third driver 130 is installed on the base 140 to move the second driver 120, the support portion 150, and/or the gripper 160 in the forward and backward direction (X direction).

The third driver 130 includes LM guides 132 and 133, a motor 135, a belt 136, pulleys 137a and 137b, a fixed member 139, etc.

The LM guides 132 and 133 extend in the forward and backward direction (X direction) on both sides of the belt 136.

The fixed member 139 is fixed to the belt 136 and/or the LM guides 132 and 133. In addition, the second driver 120 (i.e., the frame 128 of the second driver 120) is installed on an upper surface of the fixed member 139.

Two pulleys 137a and 137b are disposed to be spaced apart from each other, and the pulley 137a is connected to the motor 135. The two pulleys 137a and 137b are connected to each other by the belt 136. A rotational power of the motor 135 is provided through the belt 136 to move the fixed member 139. Therefore, the second driver 120, the support portion 150, and the gripper 160 connected to the fixed member 139 move in the forward and backward direction.

Referring to FIGS. 4 and 7, the support portion 150 includes a plate 151, a diagonal detection sensor 153, a load detection sensor 155, a fixed position sensor 157, and a plurality of pins 158.

The plurality of pins 158 may be disposed on the plate 151, and may be coupled with holes installed on a bottom surface of the third type article and/or the fourth type article.

The diagonal detection sensor 153 is installed at the rear of the plate 151 and faces a bottom surface of the plate 151. A hole 153a is formed on the bottom surface, and a reflector is disposed inside the hole 153a. The diagonal detection sensor 153 provides light to the reflector inside the hole 153a. When an article is disposed on the plate 151, the light is not reflected, and when an article is not disposed on the plate 151, the light is reflected by the reflector.

The load detection sensor 155 also checks whether an article is disposed on the plate 151. The fixed position sensor 157 checks whether the article is disposed at a fixed position.

Referring to FIGS. 4, 7, and 8, the gripper 160 includes a first gripper 160a and a second gripper 160b that are disposed to be spaced apart from each other in the left and right direction (Y direction). The first gripper 160a and the second gripper 160b operate to open or close in the left and right direction (Y direction).

Each of the first gripper 160a and the second gripper 160b includes bodies 165a and 165b, sensors 168a and 168b installed on the bodies 165a and 165b and for detecting a load, and connection portions 161a and 161b installed on the bodies 165a and 165b and connected to a lower surface of the support portion 150. The sensors 168a and 168b may be reflective beam sensors, but are limited thereto.

Meanwhile, referring to FIG. 4, a first sensing member 152a may be installed on a lower portion of the support portion 150, and a second sensing member may be installed on the base 140 at a position facing the first sensing member 152a. The control device 50 may recognize the type of article gripped by the gripper 160 based on an operation between the first sensing member 152a and the second sensing member. For example, the first sensing member 152a may be a light sensor and the second sensing member may be a reflector. The control device 50 may recognize the type of article by checking whether light provided from the first sensing member 152a is reflected by the reflector.

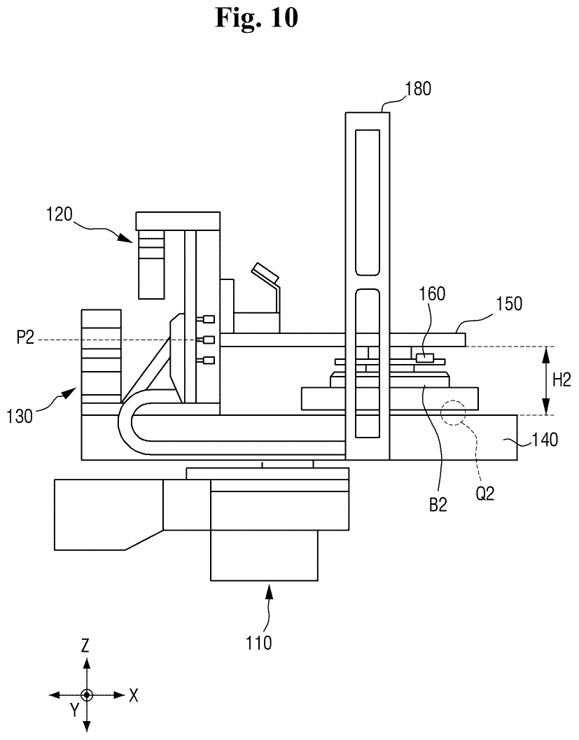

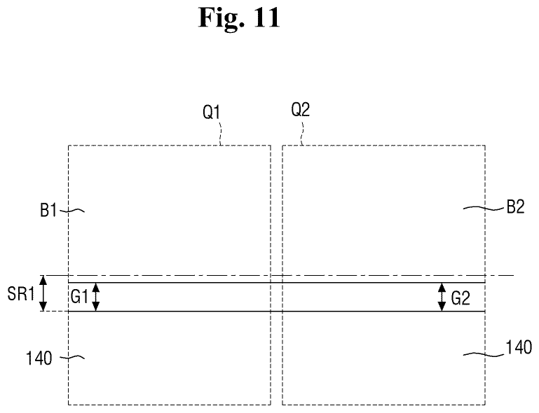

FIG. 9 is a view for describing a first operation of the system for transporting articles according to some exemplary embodiments of the present disclosure. FIG. 10 is a view for describing a second operation of the system for transporting articles according to some exemplary embodiments of the present disclosure. FIG. 11 is an enlarged view of area Q1 of FIG. 9 and area Q2 of FIG. 10.

FIG. 9 illustrates a case in which the gripper 160 grips a first type article B1 (e.g., EUV POD), and FIG. 10 illustrates a case in which the gripper 160 grips a second type article B2 (e.g., RSP-150).

Referring to FIGS. 9 and 10, the first type article B1 and the second type article B2 have different sizes (e.g., height or width). As illustrated, the height of the first type article B1 may be higher than the height of the second type article B2. When the gripper 160 grips the first type article B1, the distance between the support portion 150 and the base 140 is maintained at H1. On the other hand, when the gripper 160 grips the second type article B2, the distance between the support portion 150 and the base 140 is maintained at H2. The distance H1 and the distance H2 are different from each other.

As the position of the support portion 150 changes due to the second driver 120 (see P1 and P2), the distances H1 and H2 change from each other. For example, the lifting device 80 may be moved to a preset position regardless of the articles B1 and B2 and may then change the position of the support portion 150 using the second driver 120.

Specifically, the second driver 120 adjusts the height of the support portion 150 to the first height (corresponding to the distance H1), and the support portion 150 is moved forward in the X direction by the third driver 130. The gripper 160 grasps the first type article B1, and then the support portion 150 is moved back in the X direction by the third driver 130.

Similarly, the second driver 120 adjusts the height of the support portion 150 to the second height (corresponding to the distance H2) that is different from the first height, and the support portion 150 is moved forward in the X direction by the third driver 130. The gripper 160 grasps the second type article B2, and then the support portion 150 is moved back in the X direction by the third driver 130.

Meanwhile, as illustrated in FIG. 11, when the gripper 160 grips the first type article B1, a first distance G1 between the bottom surface of the first type article B1 and the base 140 is maintained within a first safety distance SR1. In addition, when the gripper 160 grips the second type article B2, a second distance G2 between the bottom surface of the second type article B2 and the base 140 is maintained within the first safety distance SR1.

The first type article B1 and the second type article B2 are transported in a spaced state with respect to the base 140. In order to minimize an impact on the first type article B1 and the second type article B2 even when the first type article B1 and the second type article B2 are spaced apart from the base 140, the first distance G1 and the second distance G2 need to be smaller than the first safety distance SR1. In particular, the control device 50 controls the first distance G1 and the second distance G2 to be substantially the same.

When the gripper grips an article at a constant height regardless of the type of article (i.e., the height of the article), a distance between an article with a lower height and the base is greater than a distance between an article with a higher height and the base. In this case, if the gripper drops the article with the low height, a large impact may be applied to the article with the low height.

On the other hand, in the exemplary embodiment of the present disclosure, regardless of the type of article (i.e., the height of the article), the distances between the bottom surfaces of the articles B1 and B2 and the base 140 are made substantially the same. Regardless of the type of articles, the articles may be safely transported.

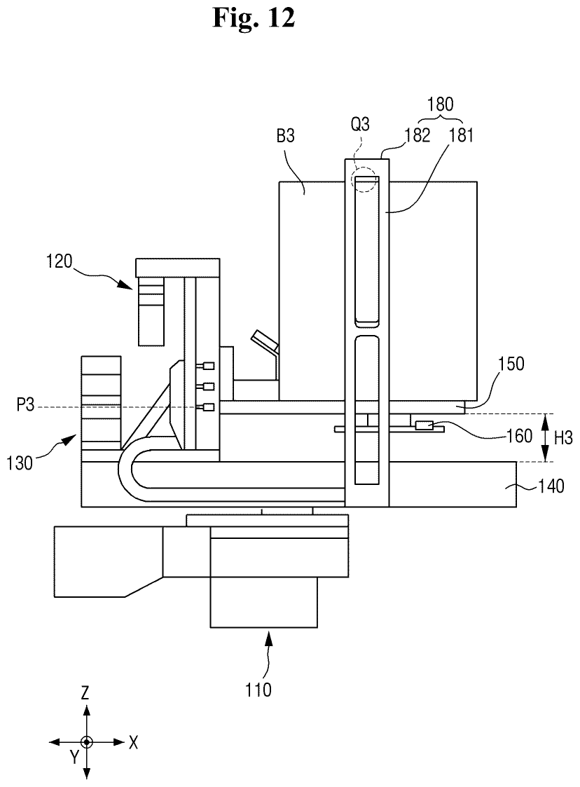

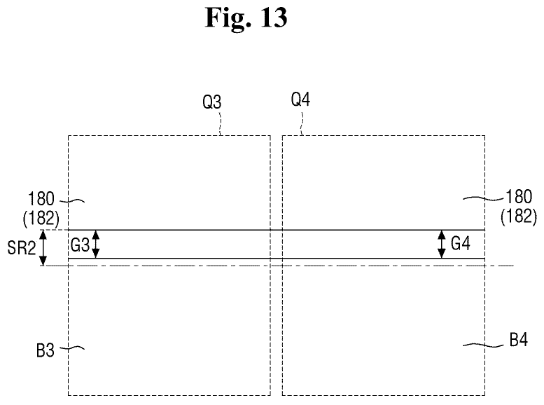

FIG. 12 is a view for describing a third operation of the system for transporting articles according to some exemplary embodiments of the present disclosure. FIG. 13 is an enlarged view of area Q3 of FIG. 12.

Referring to FIGS. 12 and 13, a third type article B3 may be a wafer storage container (e.g., FOUP), and is supported by the upper surface of the support portion 150. When the support portion 150 supports the third type article B3, the distance between the support portion 150 and the base 140 is maintained at H3. The distance H3 is different from the distances H1 and H2 described above. As the position of the support portion 150 changes due to the second driver 120 (see P3), the distance H3 changes.

For example, the second driver 120 adjusts the height of the support portion 150 to the third height (i.e., see H3), and the support portion 150 is moved forward in the X direction by the third driver 130. The third type article B3 is placed on the support portion 150, and then the support portion 150 is moved back in the X direction by the third driver 130.

In order to prevent the third type article B3 from falling, a third distance G3 between the uppermost surface of the third type article B3 and the second member 182 of the falling prevention portion 180 is maintained within a second safety distance SR2.

Meanwhile, if the support portion 150 supports a fourth type article B4 having a different height from the third type article B3, a fourth distance G4 between the uppermost surface of the fourth type article B4 and the second member 182 of the falling prevention portion 180 is maintained within the second safety distance SR2. In particular, the control device 50 controls the third distance G3 and the fourth distance G4 to be substantially the same.

As the distances between the uppermost surfaces of the articles B3 and B4 and the falling prevention portion 180 are substantially the same, regardless of the type of the article (i.e., the height of the article), the articles may be safely transported regardless of the type of articles.

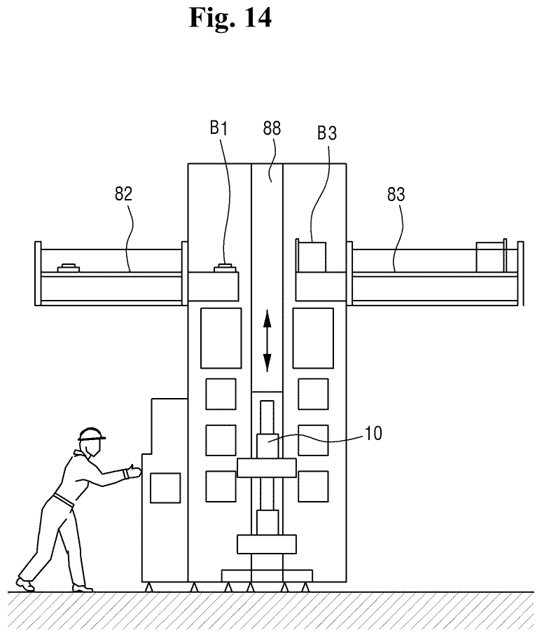

FIG. 14 is a conceptual view for describing the system for transporting articles according to some exemplary embodiments of the present disclosure. For convenience of explanation, points different from those described with reference to FIGS. 1 to 13 will be mainly described.

Referring to FIG. 14, the system for transporting articles includes a first rail 88 extending in the up-down direction, a second rail 82 disposed on a first side of the first rail 88 and installed in a horizontal direction, and a third rail 83 disposed on a second side of the first rail 88 and installed in the horizontal direction.

The robot 10 includes a first carriage device and a second carriage device as described above. Each of the first carriage device and the second carriage device includes a base, a support portion installed on the base and moving in the up-down direction with respect to the base, and a gripper installed on a lower portion of the support portion and moving along with the movement of the support portion. In addition, the gripper is configured to grip a first top flange of the first type article and a second top flange of the second type article, and the support portion is configured to support a bottom surface of a third type article.

The robot 10 (i.e., carriage device) moves along the first rail 88 and transports the first type article B1 to the second rail 82. Alternatively, the robot 10 (i.e., carriage device) moves along the first rail 88 and transports the third type article B3 to the third rail 83.

As an exemplary embodiment, the system for transporting articles may further include a fourth rail disposed on a third side of the first rail 88 and installed in the horizontal direction. The robot 10 may move along the first rail 88 and transport the second type article to the fourth rail.

While the robot 10 (i.e., the carriage device) is transporting the first type article, a first distance between a bottom surface of the first type article and the base may be maintained within a first safety distance, and while the carriage device is transporting the second type article, a second distance between a bottom surface of the second type article and the base may be maintained within the first safety distance. Here, the first distance and the second distance may be the same as each other.

Although the exemplary embodiments of the present disclosure have been described with reference to the accompanying drawings, those of ordinary skill in the art to which the present disclosure pertains will understand that the present disclosure may be embodied in other specific forms without changing the technical spirit or essential features thereof. Therefore, it should be understood that the exemplary embodiments described above are illustrative in all aspects and not restrictive.

What is claimed is:

1. A system for transporting articles, the system comprising:
a rail installed to extend in an up-down direction;
a lifting device configured to ascend and descend along the rail;
a carriage device installed on the lifting device and configured to mount a first type article or a second type article having different heights; and
a control device controlling at least one of the lifting device and the carriage device,
wherein the carriage device includes:
abase,
a support portion installed on the base and moving in the up-down direction with respect to the base, and
a gripper installed on a lower portion of the support portion to move along with the movement of the support portion and configured to grip a first top flange of the first type article and a second top flange of the second type article, and
the control device differently adjusts a distance between the support portion and the base depending on whether the gripper grips the first type article or the second type article.

2. The system of claim 1, wherein the control device maintains:
a first distance between a bottom surface of the first type article and the base within a first safety distance while the gripper grips the first type article, and
a second distance between a bottom surface of the second type article and the base within the first safety distance while the gripper grips the second type article.

3. The system of claim 2, wherein the first distance and the second distance are substantially the same.

4. The system of claim 2, wherein the control device adjusts a height of the support portion to a first height, moves forward the support portion, causes the gripper to grip the first type article, and then moves back the support portion,
the control device adjusts the height of the support portion to a second height that is different from the first height, moves forward the support portion, causes the gripper to grip the second type article, and then moves back the support portion, and
the first height and the second height are each proportional to the first distance and the second distance.

5. The system of claim 1, wherein the carriage device further includes:
a sensing member installed on the lower portion of the support portion, and
a second sensing member installed on the base at a position facing the first sensing member, and
the control device recognizes the type of article gripped by the gripper based on an operation between the first sensing member and the second sensing member.

6. The system of claim 1, wherein the carriage device is configured to mount a third type article different from the first type article and the second type article, and
an upper surface of the support portion is in contact with a bottom surface of the third type article to support the third type article.

7. The system of claim 6, wherein the carriage device further includes a falling prevention portion installed on the base and including a first member extending the up-down direction on both sides of the support portion and a second member connected to the first member and crossing the support portion.

8. The system of claim 7, wherein the carriage device is configured to mount a third or fourth type article having different heights, and is configured so that the upper surface of the support portion supports a bottom surface of the third type article or a bottom surface of the fourth type article, and
the control device maintains:
a third distance between the uppermost surface of the third type article and the second member within a second safety distance while the support portion supports the third type article, and
a fourth distance between the uppermost surface of the fourth type article and the second member within the second safety distance while the support portion supports the fourth type article.

9. The system of claim 8, wherein the third distance and the fourth distance are substantially the same.

10. The system of claim 1, further comprising:
a first driver installed on the lifting device and configured to turn the base; and
a second driver configured to move the support portion in a forward and backward direction.

11. The system of claim 1, further comprising a third driver installed on the base and configured to move the support portion in the up-down direction,
wherein the third driver includes:
a ball screw disposed in the up-down direction,
an LM guide disposed on at least one side of the ball screw, and
a fixed member having one surface fixed to the ball screw and the LM guide, and the other surface fixed to the support portion.

12. The system of claim 1, wherein the carriage device further includes a falling prevention portion installed on the base and extending in the up-down direction on both sides of the support portion.

13. A system for transporting articles, the system comprising:
a rail installed to extend in an up-down direction;
a lifting device configured to ascend and descend along the rail;
a robot installed on the lifting device; and
a control device controlling at least one of the lifting device and the robot,
wherein the robot includes a first carriage device and a second carriage device disposed in the up-down direction,
the first carriage device performs a turn motion by a first driver connected to the lifting device,
the first carriage device includes:
a base,
a support portion installed on the base,
a second driver installed on the base and moving the support portion in the up-down direction,
a third driver installed on the base and moving the support portion and the second driver in a forward and backward direction, and
a gripper installed on a lower portion of the support portion and moving along with the movement of the support portion,
the gripper is configured to grip a first top flange of a first type article and a second top flange of a second type article,
the support portion is configured to support a first bottom surface of a third type article,
the control device maintains:
a first distance between a bottom surface of the first type article and the base within a first safety distance while the gripper grips the first type article, and
a second distance between a bottom surface of the second type article and the base within the first safety distance while the gripper grips the second type article, and the first distance and the second distance are the same as each other.

14. The system of claim 13, wherein the first carriage device further includes a falling prevention portion installed on the base and including a first member extending the up-down direction on both sides of the support portion and a second member connected to the first member and installed to cross the support portion.

15. The system of claim 14, wherein the support portion is further configured to support a second bottom surface of a fourth type article,
the control device maintains:
a third distance between the uppermost surface of the third type article and the second member within a second safety distance while the support portion supports the third type article, and
a fourth distance between the uppermost surface of the fourth type article and the second member within the second safety distance while the support portion supports the fourth type article, and
the third distance and the fourth distance are the same as each other.

16. The system of claim 13, wherein the first type article is EUV POD,
the second type article is RSP-150, and
the third type article is FOUP.

17. A system for transporting articles, the system comprising:
a first rail installed to extend in an up-down direction;
a lifting device configured to ascend and descend along the first rail;
a second rail disposed on a first side of the first rail and installed in a horizontal direction;
a third rail disposed on a second side of the first rail and installed in the horizontal direction;
a carriage device installed on the lifting device and configured to mount a first type article and a second type article having different heights; and
a control device controlling at least one of the lifting device and the carriage device,
wherein the carriage device includes:
a base,
a support portion installed on the base and moving in the up-down direction with respect to the base, and
a gripper installed on a lower portion of the support portion and moving along with the movement of the support portion,
the gripper is configured to grip a first top flange of the first type article and a second top flange of the second type article,
the support portion is configured to support a bottom surface of a third type article,
the carriage device:
moves along the first rail and transports the first type article to the second rail, and
moves along the first rail and transports the second type article to the third rail,
the control device maintains:
a first distance between a bottom surface of the first type article and the base within a first safety distance while the carriage device transports the first type article, and
a second distance between a bottom surface of the second type article and the base within the first safety distance while the carriage device transports the second type article, and
the first distance and the second distance are the same as each other.

18. The system of claim 17, wherein the carriage device is configured to mount a fourth type article different from the first type article to the third type article, and
an upper surface of the support portion is in contact with a bottom surface of the fourth type article to support the fourth type article.

19. The system of claim 18, wherein the carriage device further includes a falling prevention portion installed on the base and including a first member extending the up-down direction on both sides of the support portion and a second member connected to the first member and installed to cross the support portion.

20. The system of claim 19, wherein the control device maintains:
a third distance between the uppermost surface of the third type article and the second member within a second safety distance while the carriage device transports the third type article, and
a fourth distance between the uppermost surface of the fourth type article and the second member within the second safety distance while the carriage device transports the fourth type article, and
the third distance and the fourth distance are the same as each other.
